(19) United States
(12) Patent Application Publication
(10) Pub. No.: US 2010/0187672 A1
(43) Pub. Date: Jul. 29, 2010

(54) ELECTRONIC APPARATUS AND CIRCUIT BOARD

(75) Inventor: Nobuhiro Yamamoto, Fussa-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/622,193

(22) Filed: Nov. 19, 2009

(30) Foreign Application Priority Data
Jan. 29, 2009 (JP) 2009-018759

(51) Int. Cl. H01L 23/31; H01L 23/02

(52) U.S. Cl. 257/690; 257/787; 257/E23.18; 257/E23.124

(57) ABSTRACT

According to an aspect of the present invention, there is provided an electronic apparatus including: a housing; a circuit board that is housed in the housing; a semiconductor package that includes a first surface on which solder balls are provided and a second surface opposite to the first surface and that is mounted on the circuit board so as to be electrically connected to the circuit board through the solder balls; a protective film that has a water repellency and that is applied on the circuit board so as to expose around the semiconductor package mounted on the circuit board; and a joint member that joins at least a part of a side surface of the semiconductor package and the circuit board.

### CROSS-REFERENCE TO RELATED APPLICATIONS

This application is based upon and claims the benefit of priority from Japanese Patent Application No. 2009-018759, filed on Jan. 29, 2009, the entire contents of which are incorporated herein by reference.

### BACKGROUND

1. Field

An aspect of the present invention relates to an electronic apparatus and a circuit board.

2. Description of the Related Art

Generally, a BGA (Ball Grid Array) component has a structure in which a board-joint surface of the BGA component is directly soldered to a BGA-joint surface of a circuit board. Therefore, the solder joint surface is easily affected by warp, deflection, etc. of the circuit board.

As a technique for improving mechanical strength of such a BGA component, a method of fixing an electronic component firmly to a surface of an insulating board by a conductive adhesive agent has been disclosed, for example, in JP-2006-216735-A.

However, when the electronic component is fixed to the circuit board by the adhesive member, there is a possibility that penetration of an adhesive member between a mount surface of an electronic component such as a BGA component and a component mount surface of a circuit board or leakage and spread of the adhesive member from the component mount surface of the circuit board will occur. Accordingly, when such an adhesive member is used, it is necessary to improve reliability of a product in consideration of reworkability, prevention of contamination of peripheral components, etc. as well as sufficient reinforcing strength given to the product.

### BRIEF DESCRIPTION OF THE SEVERAL VIEWS OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 illustrates an exemplary external appearance of a personal computer according to an embodiment of the invention.

FIG. 2 is an exemplary perspective view showing an electronic component mounted on a printed board according to the embodiment.

FIG. 3 is an exemplary sectional view showing a semiconductor package according to the embodiment.

FIG. 4 is an exemplary sectional view showing a module board according to the embodiment.

FIG. 5 is an exemplary sectional view showing a module board manufacturing process according to the embodiment.

FIG. 6 is an exemplary sectional view showing the module board manufacturing process according to the embodiment.

FIG. 7 is an exemplary sectional view showing the module board manufacturing process according to the embodiment.

FIG. 8 is an exemplary sectional view showing the module board manufacturing process according to the embodiment.

FIG. 9 is an exemplary sectional view showing the module board manufacturing process according to the embodiment.

FIG. 10 is an exemplary sectional view showing the module board manufacturing process according to the embodiment.

FIG. 11 is an exemplary sectional view showing the module board manufacturing process according to the embodiment.

FIG. 12 is an exemplary sectional view showing the module board manufacturing process according to the embodiment.

FIG. 13 is an exemplary sectional view showing an applied area of a water-repellent film according to the embodiment.

FIG. 14 is an exemplary view showing a state in which a joint shape of a board joint member is controlled according to the embodiment.

FIG. 15 is an exemplary view showing a state in which the joint shape of the board joint member is controlled according to the embodiment.

FIG. 16 exemplarily illustrates the reworkability-improved joint shape of the board joint member according to the embodiment.

FIG. 17 exemplarily illustrates the reworkability-improved joint shape of the board joint member according to the embodiment.

### DETAILED DESCRIPTION

Various embodiments according to the present invention will be described hereinafter with reference to the accompanying drawings. In general, according to one embodiment of the present invention, there is provided an electronic apparatus including: a housing; a circuit board that is housed in the housing; a semiconductor package that includes a first surface on which solder balls are provided and a second surface opposite to the first surface and that is mounted on the circuit board so as to be electrically connected to the circuit board through the solder balls; a protective film that has a water repellency and that is applied on the circuit board so as to expose around the semiconductor package mounted on the circuit board; and a joint member that joins at least a part of a side surface of the semiconductor package and the circuit board.

An electronic apparatus and a circuit board according to an embodiment of the invention will be described below in detail with reference to the drawings.

(Configuration of Electronic Apparatus)

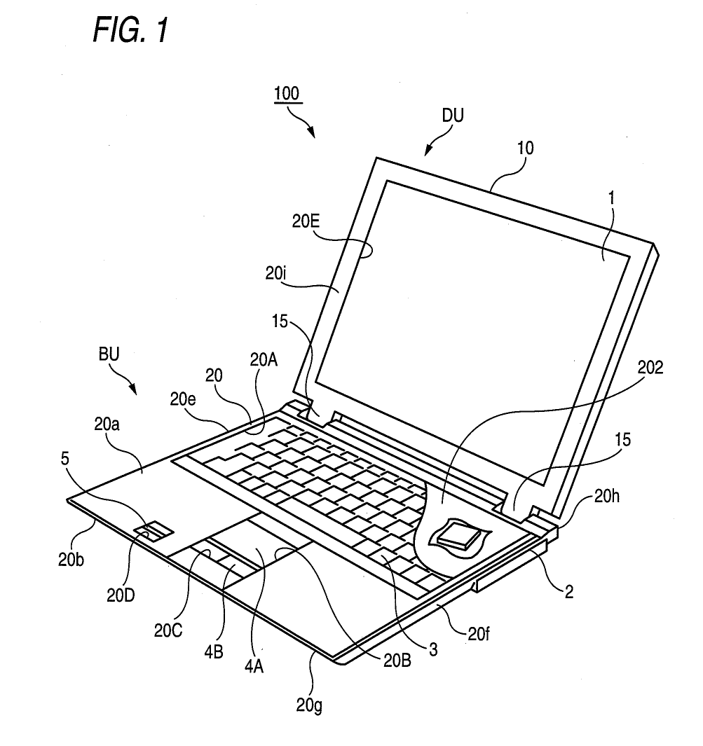

FIG. 1 illustrates an external appearance of an electronic apparatus according to an embodiment of the invention. A notebook type personal computer is disclosed as the embodiment in FIG. 1.

The personal computer 100 (electronic apparatus) according to this embodiment has a display unit DU, and a body unit BU. The display unit DU and the body unit BU are connected to each other by hinge portions 15 so that the display unit DU and the body unit BU can be folded and unfolded freely. The body unit BU has a lower housing 20. The lower housing 20 (housing) contains a body function portion 2 for processing information. The body function portion 2 includes a printed circuit board 201 (circuit board) mounted with electronic components such as a CPU (Central Processing Unit), a memory, etc.

The lower housing 20 has a top surface 20a, a bottom surface 20b, a left side surface 20e, a right side surface 20f, a front surface 20g, and a rear surface 20h. The lower housing 20 contains a character input portion 3, a track pad 4A, a decision switch 4B, and a fingerprint reading portion 5. For example, the character input portion 3 is a keyboard for inputting characters or commands. The track pad 4A serves as a pointing device. The decision switch 4B is used for inputting a selection/decision command. The fingerprint reading portion 5 is used for user authentication or the like. Opening portions 20A to 20D are formed in the top surface 20a. A hollow portion (not shown) may be formed near the opening portion 20D in the top surface 20a. The character input portion 3 is exposed from the opening portion 20A. The track pad 4A is exposed from the opening portion 20B. The decision switch 4B is exposed from the opening portion 20C. The fingerprint reading portion 5 is exposed from the opening portion 20D.

The display unit DU has an upper housing 10. The upper housing 10 contains an image display portion 1 formed of a liquid crystal panel or the like for displaying characters, images, etc. The upper housing 10 has a front surface 20i. An opening portion 20E is formed in the front surface 20i. The image display portion 1 is exposed from the opening portion 20E.

(Configuration of Circuit Board)

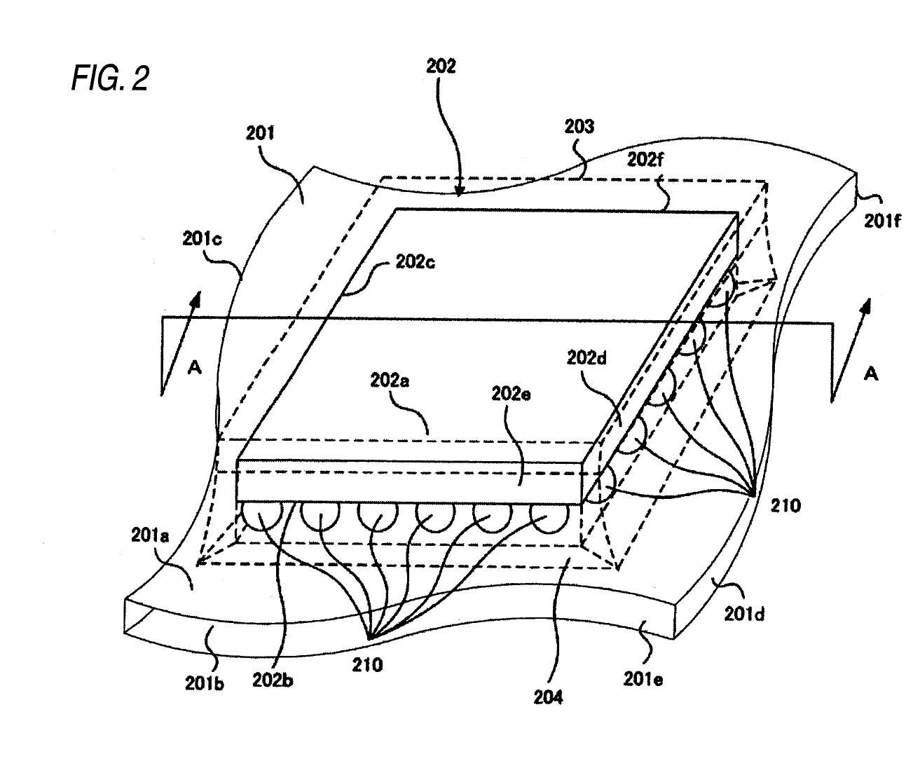

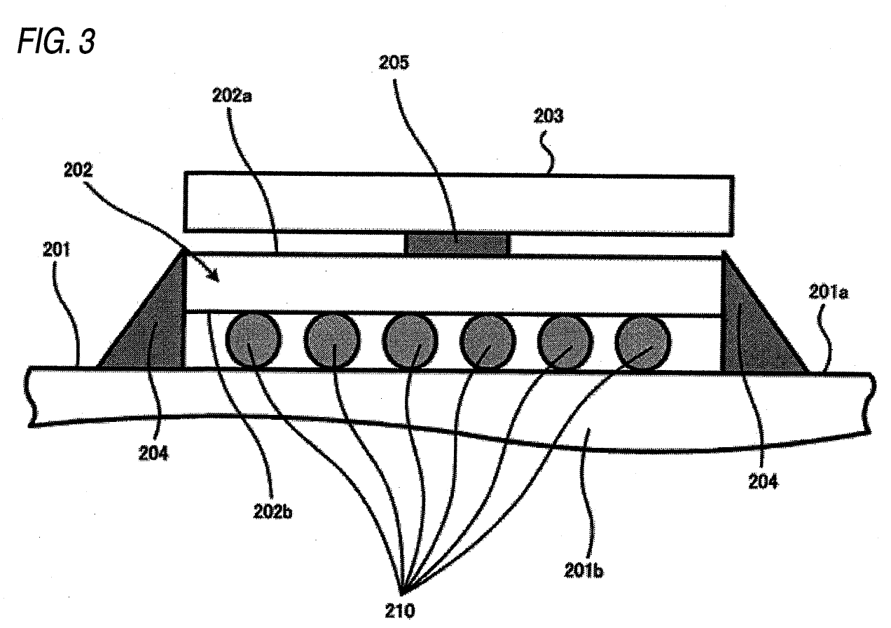

The configuration of an electronic component 202 (semiconductor package) mounted on the printed circuit board 201 according to this embodiment will be described below with reference to FIGS. 2 and 3. FIG. 2 is a perspective view showing the electronic component 202 mounted on the printed circuit board 201. FIG. 3 is a sectional view taken along the line A-A in FIG. 2.

A tape BGA (T-BGA) package (hereinafter referred to as BGA package 202) is exemplified as the electronic component 202 according to this embodiment. In FIGS. 2 and 3, the reference numeral 201 designates a printed circuit board on which various types of electronic components including a BGA package 202 are mounted; 202, the BGA package mounted on the printed circuit board 201; 203, a package protection cover for covering an upper surface 202a of the BGA package 202; and 204, a board joint member for joining the BGA package 202 to the printed circuit board 201.

The printed circuit board 201 has an upper surface 201a, and a lower surface 201b. The upper surface 201a and the lower surface 201b have circuit patterns. Various types of electronic components etc. electrically connected to the circuit patterns are mounted on the upper surface 201a and the lower surface 201b.

The BGA package 202 has an upper surface 202a, a lower surface 202b, and side surfaces 202c to 202f. The lower surface 202b has solder balls 210. The solder balls 210 are joined to the printed circuit board 201 so that the BGA package 202 is electrically connected to the printed wiring formed in the upper surface 201a of the printed circuit board 201. Specifically, in the embodiment shown in FIGS. 2 and 3, the solder balls 210 are joined to an external joint terminal portion (not shown) provided in the lower surface 202b of the BGA package 202 and to an electrode pattern of the printed circuit board 201 by melting.

In this embodiment, the package protection cover 203 is attached to a given position on the BGA package 202 so that the BGA package 202 mounted on the printed circuit board 201 is covered with the package protection cover 203. Incidentally, the BGA package 202 and the package protection cover 203 are joined to each other by a component joint member 205. The package protection cover 203 is formed of a plate of a highly thermally conductive metal such as copper, aluminum or SUS. The package protection cover 203 has an outer circumferential size larger than the outer circumferential size of a mount surface of the BGA package 202. The package protection cover 203 covers the upper surface 202a of the BGA package 202 to thereby protect the BGA package 202 from the influence of the thermal deformation or warp of the printed circuit board 201. The package protection cover 203 has a function of releasing heat generated in a semiconductor chip (not shown) in the BGA package 202 to the outside while relaxing stress imposed on the external joint terminal portion of the package lower surface due to the thermal deformation or warp of the printed circuit board 201. A cover mount pattern (not shown) for mounting the package protection cover 203 is formed in a given position on the printed circuit board 201 across a mount position of the BGA package 202.

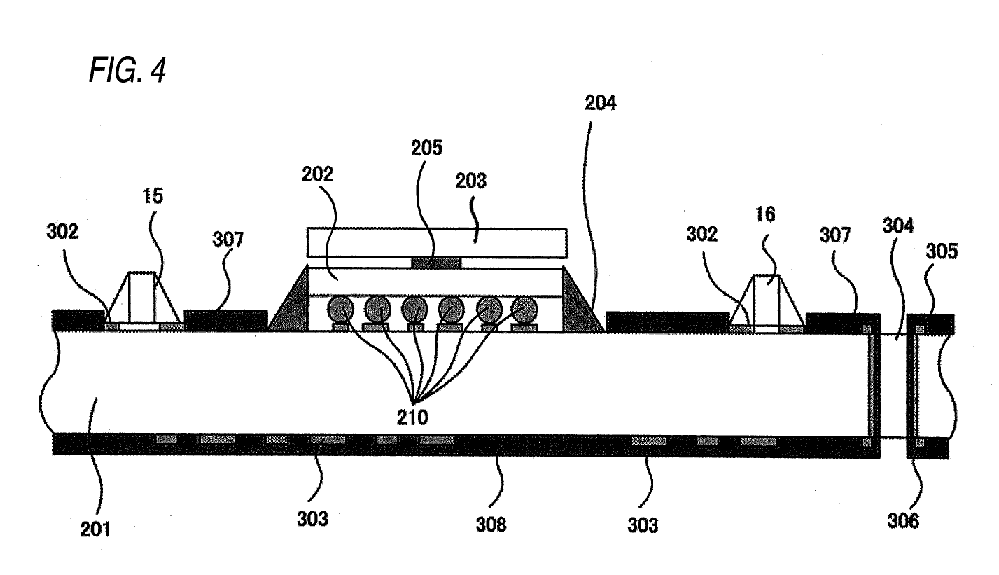

The circuit board on which the BGA package 202 is mounted according to this embodiment will be described below. FIG. 4 shows the circuit board on which the BGA package 202 is mounted according to this embodiment.

As shown in FIG. 4, the printed circuit board 201, for example, formed of a glass epoxy resin, has circuit patterns 302 and 303 formed on its front and rear surfaces respectively. A through-hole 304 is formed in the printed circuit board 201 so as to pass therethrough. Lands 305 and 306 are formed on the front and rear surfaces of the printed circuit board 201 so as to be disposed near opposite end opening portions of the through-hole 304. Water-repellent films 307 and 308 which are protective films are formed on the front and rear surfaces of the printed circuit board 201 including the circuit patterns 302 and 303. The water-repellent film 307 on the front surface side is applied on at least near the mount region of the BGA package 202. In this embodiment, the water-repellent film 307 is applied so that openings are also formed in places of the circuit pattern 302 and the land 305 in which other components of active and passive elements than the BGA package 202 are mounted.

The water-repellent film 308 on the rear surface side has an opening formed in the place of the land 306. As described above, the printed circuit board 201 according to this embodiment includes the circuit patterns 302 and 303, the through-hole 304 provided with the lands 305 and 306, and the water-repellent films 307 and 308.

Electrodes of the BGA package 202 are connected, through the solder balls 210, to the circuit pattern 302 exposed from the opening (mount region) of the water-repellent film 307 on the front surface side of the printed circuit board 201. The board joint member 204 is interposed between the printed circuit board 201 and the BGA package 202 in the mount region, so that the BGA package 202 is mechanically fixed to the printed circuit board 201. The passive element components (such as chip resistors) 15 and 16 are connected to the circuit pattern 302 exposed from the opening (mount region) of the water-repellent film 307 on the front surface side of the printed circuit board 201.

In this embodiment, a liquid adhesive agent such as an underfill can be used as the board joint member 204. Besides the chip resistors, for example, chip capacitors can be used as the passive element components.

In this embodiment, a fluororesin or the like, for example, formed of polytetrafluoroethylene (PTFE), tetrafluoroethylene-perfluoroalkyl vinyl ether copolymer (PFA), tetrafluoroethylene-hexafluoropropylene copolymer (FEP), tetrafluoroethylene-ethylene copolymer (ETFE), polyvinylidene fluoride (PVDF), or polychlorotrifluoroethylene (PCTFE) can be used as the water-repellent.

As described above, the printed circuit board 201 according to this embodiment utilizes the water repellency of the water-repellent to prevent the leakage and spread of the adhesive agent including water. In this embodiment, by controlling the water-repellent applying region, it is possible to prevent the adhesive agent from penetrating into regions or spaces undesirable in terms of penetration of the adhesive agent. Since the adhesive agent is prevented from penetrating into the peripheral region of the BGA package 202, the space between the printed circuit board 201 and the BGA package 202 and the through-hole, reliability of the electronic apparatus including the printed circuit board 201 can be improved.

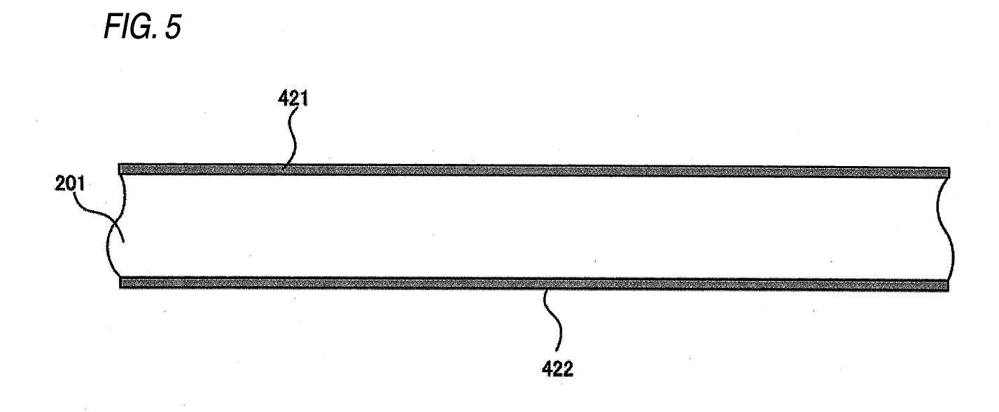

A method of manufacturing the printed circuit board 201 shown in FIG. 4 will be described below with reference to FIGS. 5 to 9. FIGS. 5 to 9 illustrate steps in the method of manufacturing the printed circuit board 201 according to this embodiment.

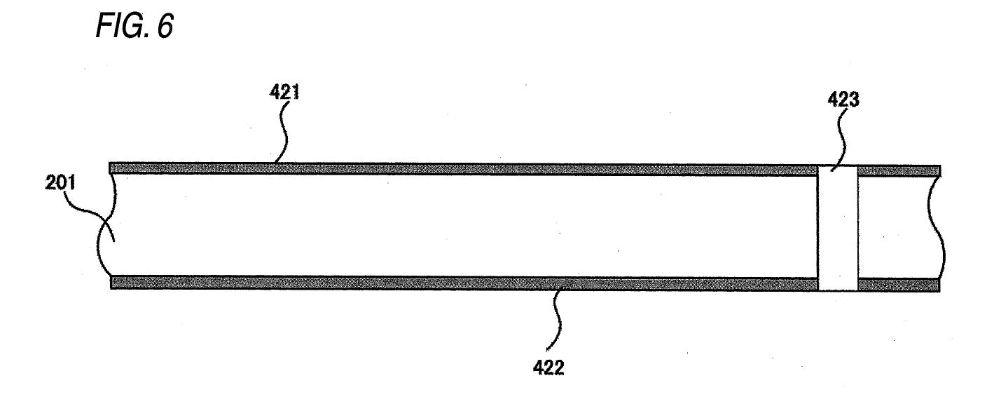

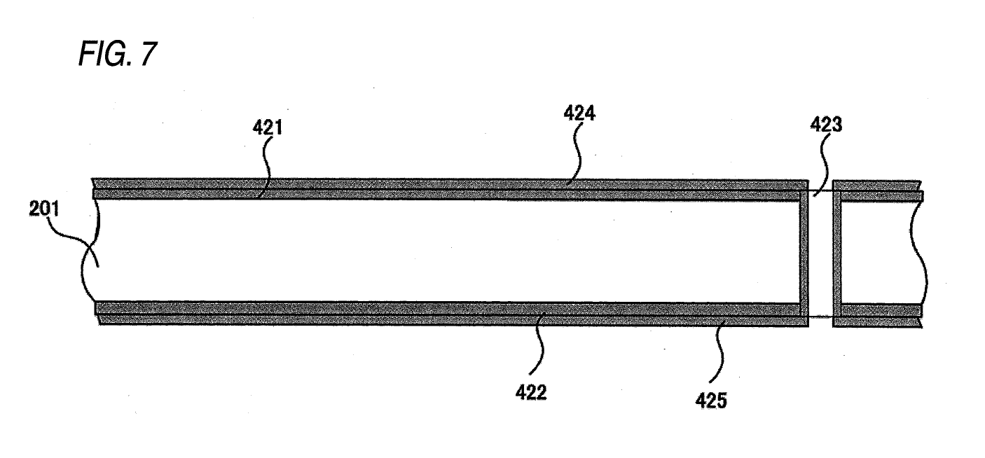

First, as shown in FIG. 5, there is prepared a so-called double-face copper-clad board having two pieces of copper foil 421 and 422 stuck to the front and rear surfaces of the printed circuit board 201, for example, made of a glass epoxy resin. Then, as shown in FIG. 6, a hole 423 is formed in the double-face copper-clad board by a drill or the like. Then, electroplating (e.g. copper electroplating) is applied to the double-face copper-clad board so that a through-hole 304 is formed in the place of the hole 423 while copper electroplating films 424 and 425 are formed on the copper foils 421 and 422 as shown in FIG. 7.

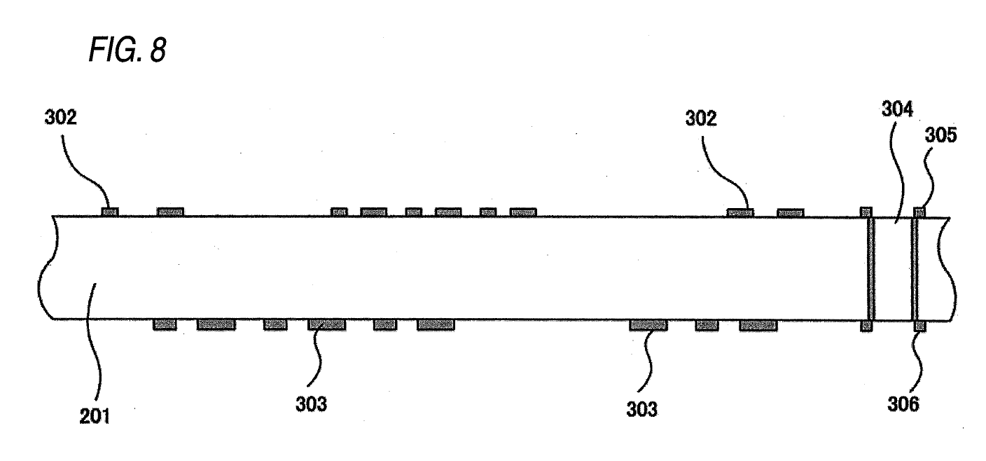

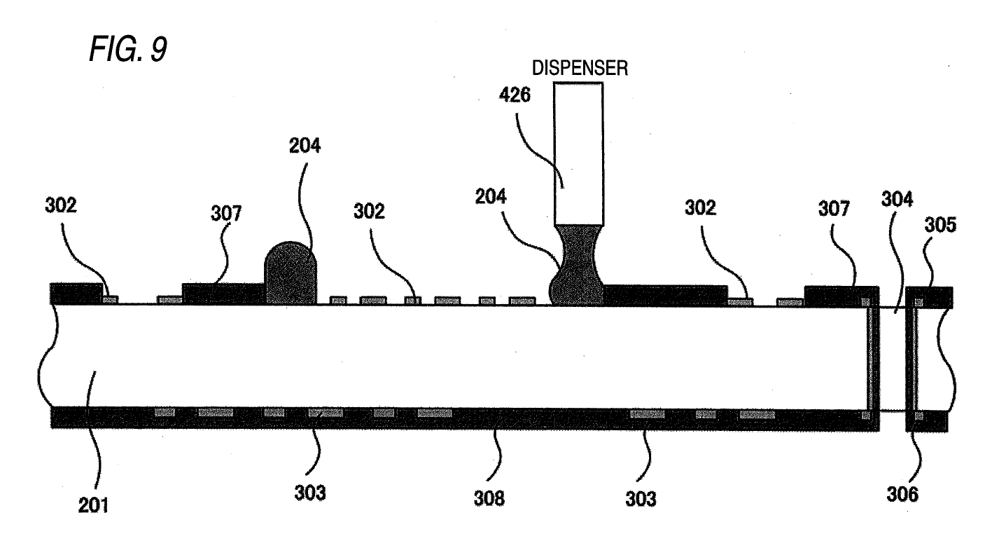

Then, as shown in FIG. 8, circuit patterns 302 and 303 are formed on the front and rear surfaces of the printed circuit board 201 by selectively etching the copper foils 421 and 422 and the copper electroplating films 424 and 425 masked with an unshown resist pattern on the front and rear surfaces of the printed circuit board 201. Then, as shown in FIG. 9, water-repellent films 307 and 308 are applied on the front and rear surfaces of the printed circuit board 201 including the circuit patterns 302 and 303 at least near the mount region of the BGA package 202. In this embodiment, the water-repellent films 307 and 308 are formed so that openings are formed in the place of the circuit pattern 302 on which an electronic component is mounted, and in the place of the land 305.

To form the water-repellent films 307 and 308, for example, a desired pattern of a film-like water-repellent may be stuck to the front and rear surfaces of the printed circuit board 201 by an adhesive agent, or a water-repellent solution may be applied by a print technique and then baked.

Then, as shown in FIG. 9, a board joint member 204 is applied by a dispenser 426 and electrodes of the BGA package 202 are connected, through solder balls 210, to the circuit pattern 302 exposed from the opening (mount region) of the water-repellent film 307 on the front surface side of the printed circuit board 201.

A joint-member forming resin solution (e.g. an epoxy resin solution containing a filler) is dropped from a dispenser nozzle into the space between the mount region of the printed circuit board 201 having the circuit pattern 302 and the BGA package 202, dried and cured to thereby form the board joint member 204 for mechanically fixing the BGA package 202 on the printed circuit board 201. Passive element components (such as chip resistors) 15 and 16 are mounted on the circuit pattern 302 exposed from the opening (mount region) of the water-repellent film 307 on the front surface side of the printed circuit board 201.

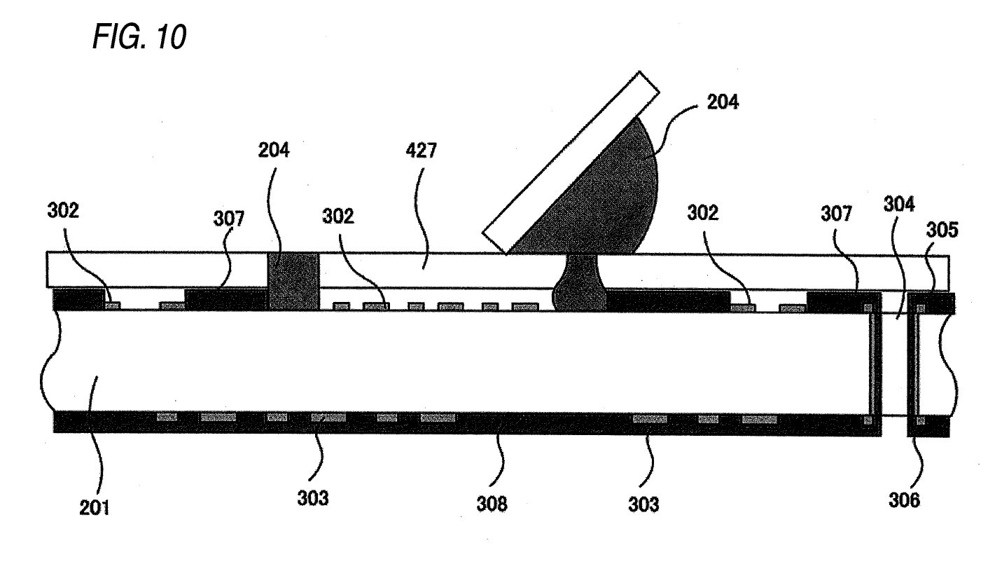

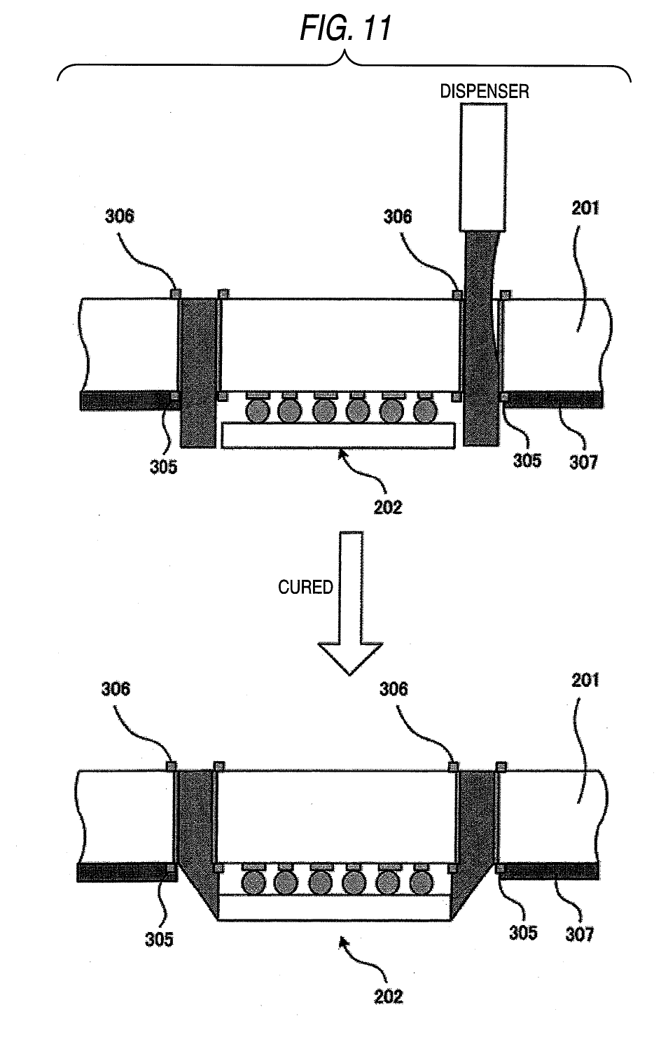

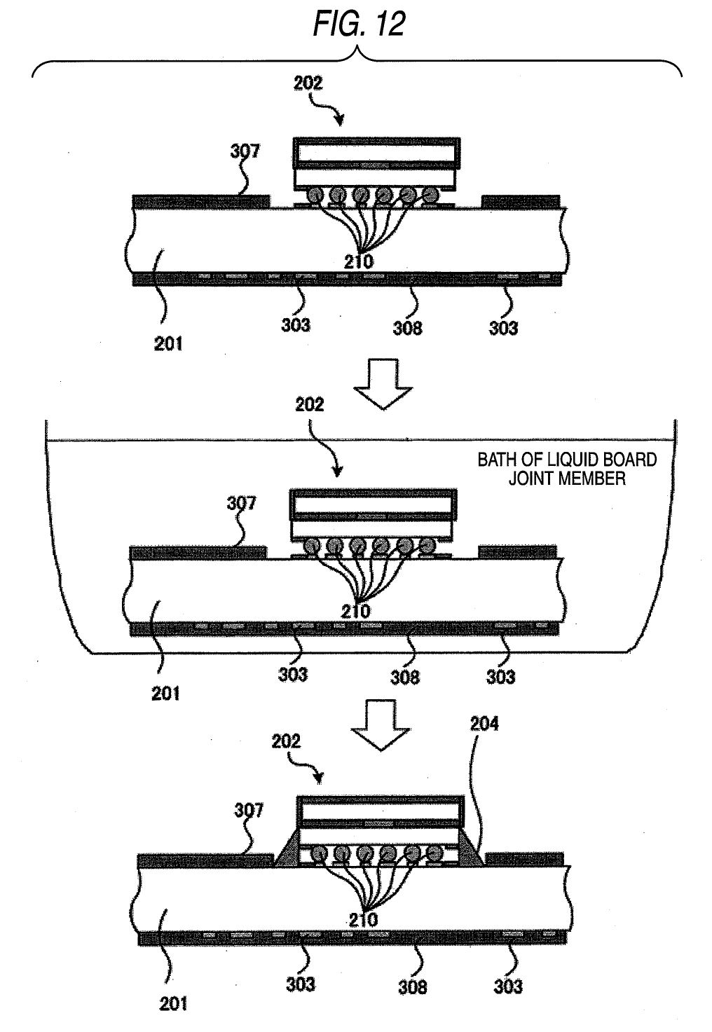

The method of applying the board joint member 204 in this embodiment is not limited to the coating method using the dispenser. For example, a liquid board joint member 204 may be poured from above a printing plate 427 in which the region to be coated with the board joint member 204 is opened as shown in FIG. 10, a liquid board joint member 204 may be poured from a through-hole formed in a circumferential edge of the BGA package 202 as shown in FIG. 11, or a water-repellent may be applied on the whole surface of the region not to be coated with the board joint member 204 in the printed circuit board 201 and then putting the printed circuit board 201 in a bath of a liquid board joint member 204 to thereby provide the board joint member 204 as shown in FIG. 12.

In this embodiment, a module board is manufactured in such a manner that the BGA package 202 and other electronic components are mounted on the printed circuit board 201 by the aforementioned steps.

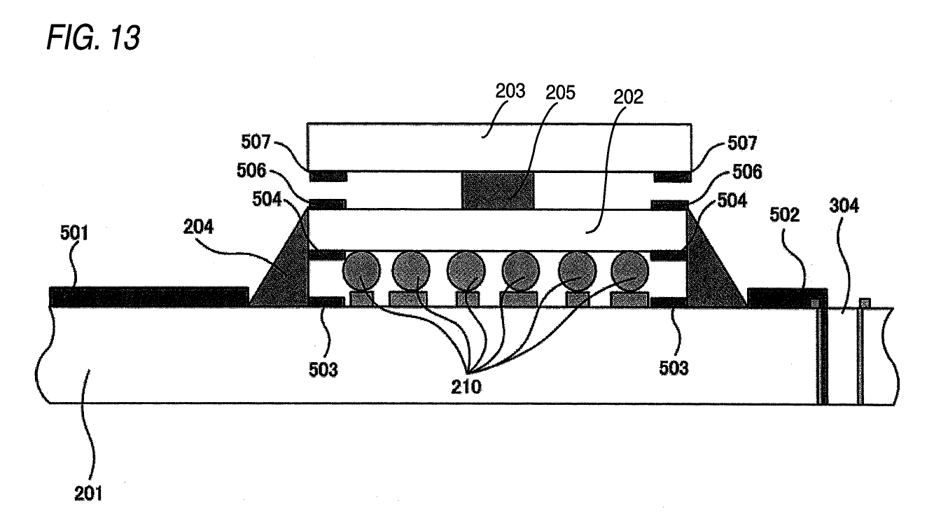

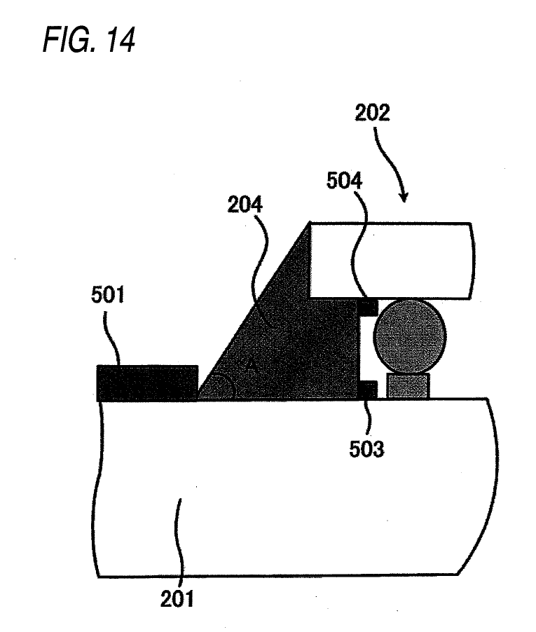

A method of applying the water-repellent films in this embodiment will be described below with reference to FIGS. 13 to 17. FIG. 13 illustrates a region on which the water-repellent film 307 is applied according to this embodiment. FIGS. 14 to 17 illustrate states in which the applying range of the water-repellent film 307 is adjusted to control the joint shape of the board joint member 204.

As shown in FIG. 13, a water-repellent film 501 in this embodiment is applied on near the mount region of the BGA package 202 on the printed circuit board 201. The board joint member 204 is provided in the mount region so as to be interposed between the printed circuit board 201 and the BGA package 202. According to the water repellency of the water-repellent film 501, the board joint member 204 is prevented from being leaked and spread onto the printed circuit board 201. A water-repellent film 502 is applied on the circumferential edge and inside of the through-hole 304. The water-repellent film 502 prevents the board joint member 204 from penetrating into the inside of the through-hole 304 and being leaked and spread onto the rear side of the printed circuit board 201 via the through-hole 304.

A water-repellent film 503 is applied on a region of the printed circuit board 201 facing the mount surface of the BGA package 202. A water-repellent film 504 is applied on a circumferential edge region in the mount surface of the BGA package 202. The water-repellent films 503 and 504 prevent the board joint member 204 from penetrating between the BGA package 202 and the region of the printed circuit board 201 facing the mount surface of the BGA package 202. A water-repellent film 506 is applied on a region of the BGA package 202 facing the package protection cover 203. A water-repellent film 507 is applied on a region of the package protection cover 203 facing the BGA package 202. The water-repellent films 506 and 507 prevent the board joint member 204 from penetrating between the BGA package 202 and the package protection cover 203.

In this embodiment, the region on which the water-repellent film 307 is applied can be adjusted to attain balance between characteristics such as durability against thermal fatigue, durability against external shock, reworkability, etc. For example, when the regions on which the water-repellent films 501, 503 and 504 are applied are provided as shown in FIG. 14, the board joint member 204 is joined to a side surface of the BGA package 202 at a steep slope represented by an angle A and joined by penetration between the BGA package 202 and the region of the printed circuit board 201 facing the mount surface of the BGA package 202. In the embodiment shown in FIG. 14, durability against thermal fatigue and durability against external shock can be enhanced.

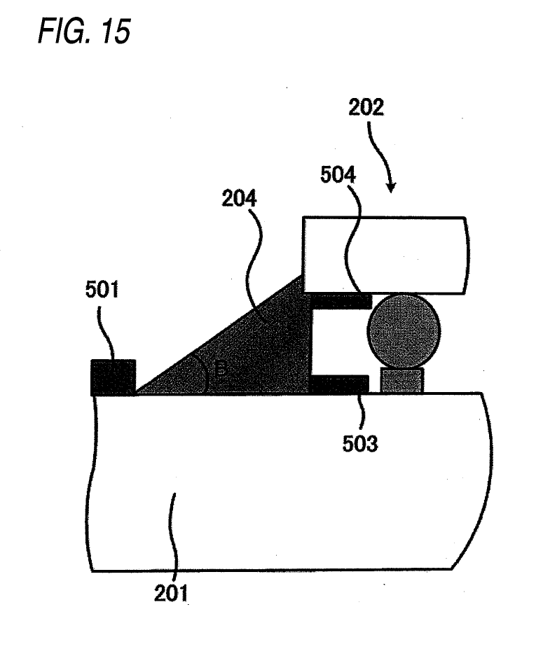

For example, when the water-repellent films 501, 503 and 504 are provided as shown in FIG. 15, the board joint member 204 is joined to a side surface of the BGA package 202 at a gentle slope represented by an angle B. Moreover, the amount of the board joint member 204 penetrating between the BGA package 202 and the region of the printed circuit board 201 facing the mount surface of the BGA package 202 is reduced compared with the embodiment shown in FIG. 14. In the embodiment shown in FIG. 15, reworkability can be enhanced.

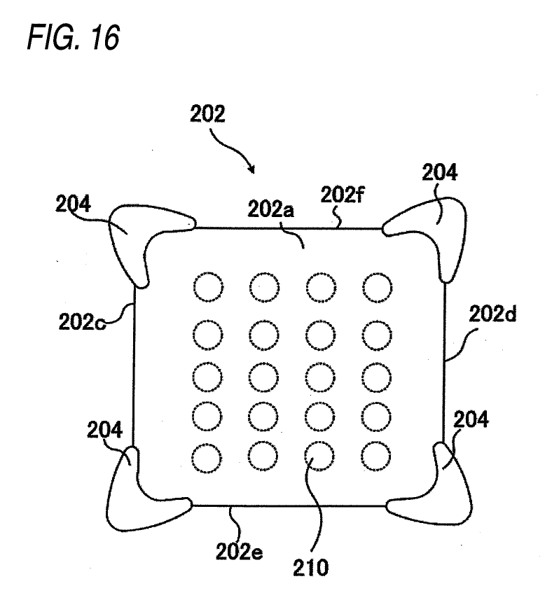

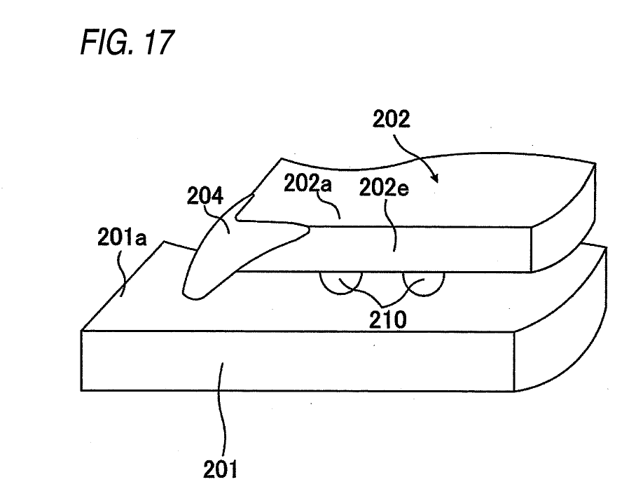

FIGS. 16 and 17 show an exemplary form in which reworkability is improved according to the embodiment. FIG. 16 illustrates the reworkability-improved form of the board joint member, viewed from the top surface of the board. FIG. 17 is a perspective view showing the reworkability-improved form. The form shown in FIGS. 16 and 17 can be achieved, for example, by previously applying the water-repellent film 307 not only on the printed circuit board 201 and a surface of the BGA package 202 facing the printed circuit board 201 but also on side surfaces, etc. of the BGA package 202.

This embodiment is configured so that the joint area between the printed circuit board 201 and the board joint member 204 is narrowed while the joint area between the BGA package 202 and the board joint member 204 is enlarged. Specifically, the water-repellent film 307 is applied on regions of side surfaces 202c, 202d, 202e and 202f of the BGA package 202 except corner edges of the BGA package 202. That is, the water-repellent film 307 is applied on four regions to be shorter than four sides of the BGA package 202. As a result, the BGA package 202 and the board joint member 204 can be joined to each other at the four corners of the BGA package 202. As each coverage range of the water-repellent film 307 becomes close to a corresponding side of the BGA package 202, the joint strength is reduced. As each coverage range of the water-repellent film 307 becomes shorter than a corresponding side of the BGA package 202, the joint strength is enhanced.

A coverage range of the water-repellent film 307 on the printed circuit board 201 is set on a region except regions corresponding to the four corners of the BGA package 202. That is, the water-repellent film 307 is applied on the printed circuit board 201 so that four openings corresponding to the four corners of the BGA package 202 are formed on the printed circuit board 201.

As a result, the printed circuit board 201 and the board joint member 204 can be joined to each other at the four corners. As the area of each opening formed in the water-repellent film 307 becomes smaller, the joint strength is reduced. As the area of each opening formed in the water-repellent film 307 becomes larger, the joint strength is enhanced. According to this embodiment, durability against external shock and reworkability are concurrently improved.

As described above, according to this embodiment, the water-repellent film 307 is applied on near the mount region of the BGA package 202 so that the board joint member 204 can be prevented from being leaked and spread onto peripheral components from the mount region of the BGA package 202 or can be prevented from penetrating between the printed circuit board 201 and the BGA package 202 when electrodes of the BGA package 202 are connected to the circuit pattern 302 through the solder balls 210 and the BGA package 202 is mechanically fixed to the printed circuit board 201 by the board joint member 204. As a result, dams and grooves heretofore used for preventing penetration are not required. Because the distance between respective components can be reduced, it is possible to provide a module board on which components such as a BGA package 202 are mounted at high density.

In the module board including the printed circuit board 201, when the BGA package 202 as a defective component mounted on the circuit board 201 needs to be exchanged for a new active element component, the BGA package 202 can be easily exchanged for a new one without damaging peripheral components because the board joint member 204 can be prevented from being spread onto the peripheral components from the mount region of the BGA package 202 in the printed circuit board.

Although this embodiment has been described in the case where a printed circuit board having circuit patterns formed on its opposite surfaces is used, the invention is not limited thereto. For example, a printed circuit board having a circuit pattern formed on its single surface or a multilayer printed circuit board having inner layer circuit patterns in its inside may be used.

The invention is not limited only to the aforementioned embodiment per se, but can be embodied by modification of constituent members in practical use without departing from the scope and spirit of the invention. A plurality of constituent members disclosed in the aforementioned embodiment may be combined suitably to form various inventions. For example, several constituent members may be removed from all the constituent members disclosed in the embodiment. In addition, constituent members disclosed in different embodiments may be combined suitably.

According to an aspect of the present invention, reliability of a product can be improved.

What is claimed is:

1. An electronic apparatus comprising:
a housing;
a circuit board in the housing;
a semiconductor package comprising a first surface and solder balls on the first surface and a second surface opposite to the first surface on the circuit board electrically connected to the circuit board through the solder balls;
a first water repellent protective film on the circuit board around the semiconductor package; and
an adhesive on at least a portion of a side surface of the semiconductor package and the circuit board.

2. The electronic apparatus of claim 1,
wherein a second water repellent protective film is on a region of the circuit board facing the semiconductor package in order to prevent the adhesive from flowing into an area between the circuit board and the semiconductor package.

3. The electronic apparatus of claim 2,
wherein a third water repellent protective film is on the first surface of the semiconductor package in order to prevent the adhesive from flowing into the area between the circuit board and the semiconductor package.

4. The electronic apparatus of claim 3, further comprising:
a heat radiator thermally connected to the second surface of the semiconductor package,
wherein a fourth water repellent protective film is on the second surface of the semiconductor package facing a first surface of the heat radiator in order to prevent the adhesive from flowing into the area between the semiconductor package and the heat radiator.

5. The electronic apparatus of claim 4,
wherein a fifth water repellent protective film is on the first surface of the heat radiator facing the second surface of the semiconductor package in order to prevent the adhesive from flowing into the area between the semiconductor package and the heat radiator.

6. The electronic apparatus of claim 5,
wherein a through hole is in the circuit board, and
wherein a sixth water repellent protective film is on a circumferential edge of the through-hole in order to prevent the adhesive from flowing into the through-hole.

7. The electronic apparatus of claim 1,
wherein the adhesive is on regions corresponding to two diagonal corners of the semiconductor package, and
wherein the first water repellent protective film is on circumferential edges of the regions comprising the adhesive on the regions in order to prevent the adhesive from flowing out of the regions.

8. The electronic apparatus of claim 7,
wherein the adhesive is on the circuit board in such a manner that at least one portion of the adhesive is between the circuit board and the semiconductor package.

9. A circuit board comprising:
a board;
a circuit pattern on the board;
a semiconductor package comprising a first surface comprising solder balls on the first surface and a second surface opposite to the first surface on the board electrically connected to the circuit pattern through the solder balls;
a first water repellent protective film on the board around the semiconductor package; and
an adhesive on at least a portion of a side surface of the semiconductor package and the board.

10. The circuit board of claim 9,
wherein a second water repellent protective film is on a region of the board facing the semiconductor package.
